(19) United States
(12) Patent Application Publication
(10) Pub. No.: US 2024/0120173 A1
(43) Pub. Date: Apr. 11, 2024

(54) EBEAM INSPECTION

(71) Applicant: VueReal Inc., Waterloo (CA)

(72) Inventors: Gholamreza CHAJI, Waterloo (CA); Ehsanollah FATHI, Waterloo (CA); Chang Ho PARK, Waterloo (CA)

(73) Assignee: VueReal Inc., Waterloo, ON (CA)

(21) Appl. No.: 18/263,406

(22) PCT Filed: Jan. 28, 2022
(86) PCT No.: PCT/CA2022/050118

§ 371 Date: Jul. 28, 2023

Related U.S. Application Data
(60) Provisional application No. 63/143,220, filed on Jan. 29, 2021.

(51) Int. Cl. H01J 37/252; H01J 37/063; H01J 37/09; H01J 37/24

(52) U.S. Cl. CPC H01J 37/252; H01J 37/063; H01J 37/09; H01J 37/243

(57) ABSTRACT

The present disclosure relates to integrating microdevices into a system substrate. In particular it relates to measuring microdevices using an electron beam method using one or several tips as Ebeam sources. The disclosure further outlines methods to target Ebeams effectively to produce an optimum result with minimal damage to adjacent microdevices and components.

### BACKGROUND AND FIELD OF THE INVENTION

The present disclosure relates to integrating microdevices into a system substrate.

### SUMMARY

According to one embodiment the present invention discloses a method to activate a microdevice with an electron beam, the method comprising, having the microdevice in a substrate, having an electron beam source, having at least one electrode of the microdevice biased by a second electrode or a probe, having at least one electrode a part of the biasing circuits in the substrate, and activating the microdevice passing the electron beam through a pad to the microdevice to at least one electrode.

### BRIEF DESCRIPTION OF THE DRAWINGS

The foregoing and other advantages of the disclosure will become apparent upon reading the following detailed description and upon reference to the drawings.

FIG. 1A shows the use of electron beams directed at devices in the system substrate or donor substrate.

FIG. 1B shows a structure that a protective layer covers some of the surfaces on the substrate, part of the microdevice pads and microdevice surface.

FIG. 1C shows one structure of electron source.

FIG. 1D shows there are more tips in the substrate compared to the microdevices on the substrate.

FIG. 1E shows a protection electrode protecting the other surface and the microdevice from unwanted electron beams.

The present disclosure is susceptible to various modifications and alternative forms, specific embodiments or implementations have been shown by way of example in the drawings and will be described in detail herein. It should be understood, however, that the disclosure is not intended to be limited to the particular forms disclosed. Rather, the disclosure is to cover all modifications, equivalents, and alternatives falling within the spirit and scope of an invention as defined by the appended claims.

### DETAILED DESCRIPTION

In this description, the term “device” and “microdevice” are used interchangeably. However, it is clear to one skilled in the art that the embodiments described here are independent of the device size.

To develop a system (display, sensors or other), microdevices are integrated into a system substrate.

Microdevices can be microLED or sensors or MEMS or OLEDs or etc. A system substrate consists of a substrate and backplane circuitry which control the microdevices by biasing the microdevices.

The microdevices can be in different forms such as vertical where at least one contact is at the top and one contact is at the bottom surface of the device.

One approach to develop a solid state system made out of an array of optoelectronic devices (or other types of solid state devices) is to integrate microdevices into the system substrate. Microdevices are solid state devices made out of active layers, ohmic, contact and or pads. The microdevices can be microLED, micro sensors, micro chiplet, and so on. The microdevices are formed on a substrate and then transferred (or formed on) to a donor substrate. The microdevices are then transferred from the donor substrate into the system substrate. The system substrate can have different circuitry including pixels, electrodes, and pads for coupling to microdevices. The transfer can be done by different means. The microdevice can couple to the system substrate through different approaches such as deposition of conductive electrode or conductive bonding (e.g., eutectic, metallic, thermal, etc.). The microdevices on the donor or the system substrate are tested to identify the defects and performance of the microdevice. In one case, the defective microdevice can be replaced by a working microdevice which is called a repair process.

Measuring microdevices before and after integration into a system substrate is a major hurdle for developing high yield microdevice systems such as microLED displays.

In donor substrate, microdevices have higher pitch (very close to each other). As a result, to measure each device without causing interference, one needs to be able to measure devices selectively. For example, if the donor substrate has a 10 micrometer microLED pitch, turning one microLED ON can impact the result of the adjacent devices. Selective measurement of devices in such packed environments is challenging and may not be reliable and/or expensive.

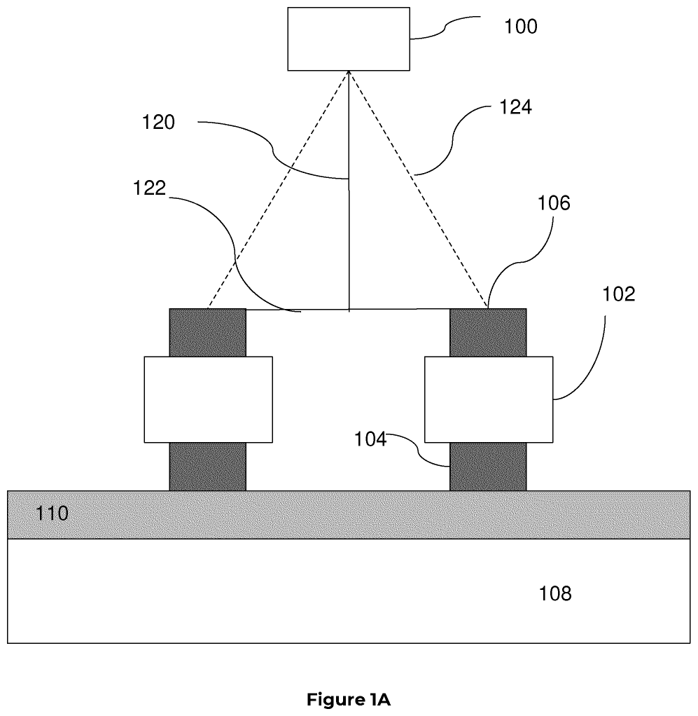

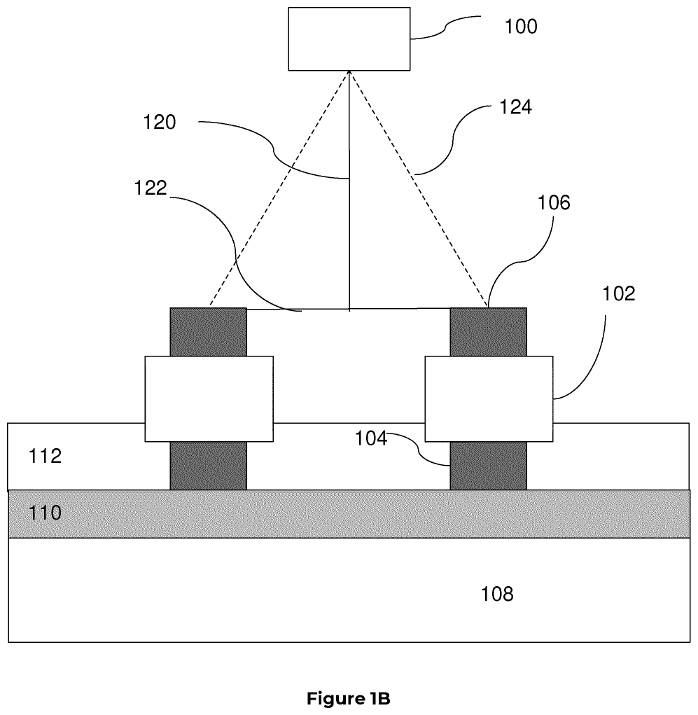

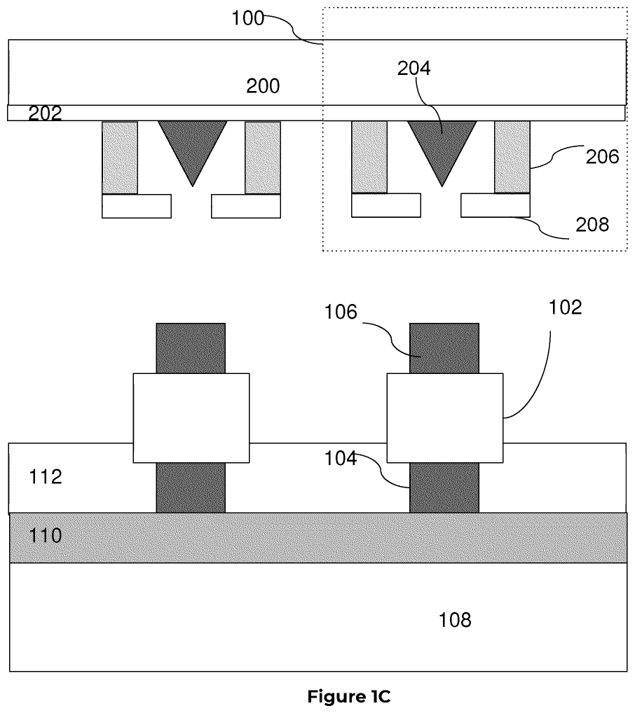

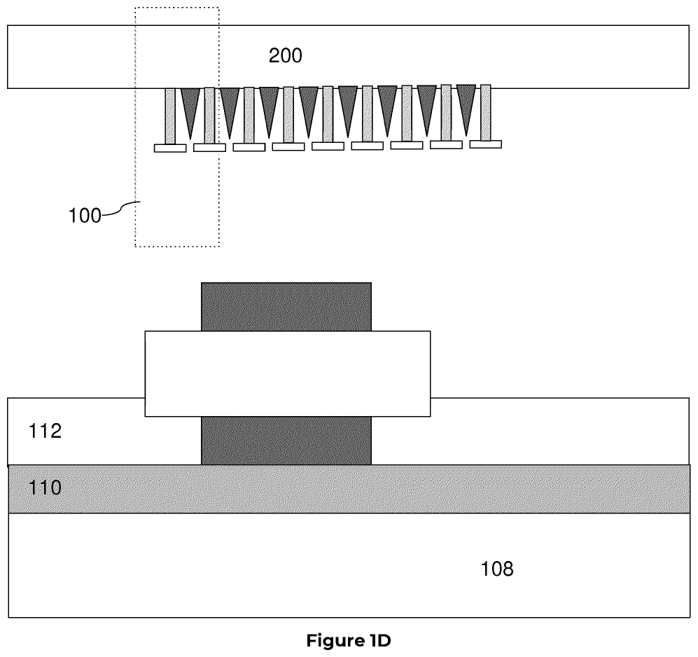

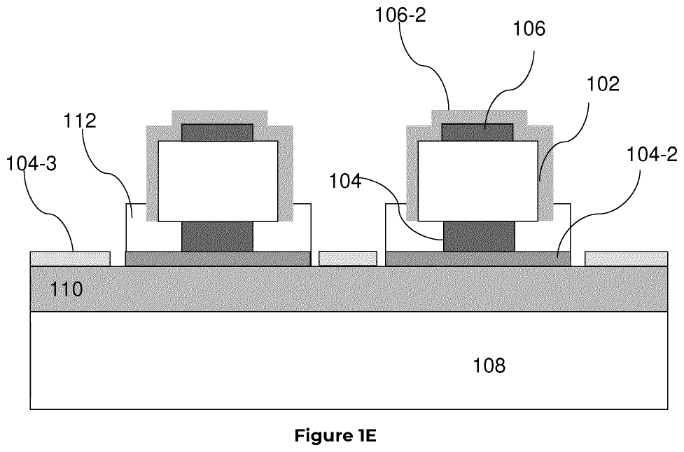

In another case, some devices (e.g., vertical or lateral) when transferred into system substrate are not fully functional as some of the electrodes are not connected to the device yet. At this point, measuring the devices to make sure the transfer process, the substrate and microdevice is functional is crucial. This is because after connecting the electrodes, it will be challenging to repair or fix the devices. As shown in FIG. 1A to enable electrical coupling to the device 100 after the transfer, a pad 106 is formed on the bottom surface of the device 100. A dielectric shell 108 can be developed which is surrounding the pads. The dielectric shell 108 can be adhesive.

FIG. 1A shows the use of electron beams from an electron source 100 directed at microdevice 102 in a system substrate 108 or a donor substrate 108 (from here called substrate) to activate the microdevice 102.

At least one connection 104 of the microdevice 102 is biased by a probe or an electrode. Another connection 106 is biased by the ebeam 124. An electron source 100 is used to direct at least part of the electron beam 124 to a microdevice contact 106. The electron beam 124 passes through one contact 106 of the device to the microdevice 102 and to the said electrode 104 biased by the probe or the electrode. The part of electrode 104 can be part of the biasing circuits 110 in the substrate 108. The biasing circuit can be simple electrode or pixel circuits with complex functions such as control of the duty cycle, signal strength and so on.

The electron source can scan more than one microdevice in the substrate. In one case, a magnetic/electric field is used to redirect the electron beam 124 to different microdevices. In this case, if the distance 120 of beam source is further away from the microdevice 102, the effective spot size 122 of the beam 124 becomes larger. As a result, the electron beam 124 will cover other areas different from the microdevice contact 106. As a result, the current value will change. Here, the electron beam 124 power can be modified to compensate for the change in the current density. In another case, the electron source is moved closer to the microdevice (here the electron source is aligned with the device). Therefore, the beam shape is the same for the microdevices. In another case, a combination of the two approaches is used. The magnetic or electric field is used to direct the beam to some distance till the current density stays within a threshold value. Then the electron source is moved to a new position.

The electron beam can affect the microdevice surface other than the contact area 106 or the surfaces on the substrate 108 not coupled to the contact 106. As a result, the beam can directly damage those areas or the charge can accumulate on those areas damaging the area through a discharge. FIG. 1B shows a structure where a protective layer 112 covers some of the surfaces on the substrate, part of the microdevice pads 104 and microdevice surface. The protective layer can be a dielectric or conductive layer redirecting the excess charge.

FIG. 1C shows one structure of electron beam source 100. Here, substrate 200 has a circuit layer 202. The circuit layer has either electrodes or other circuitry to control the voltage or current going through a tip 204. The tip can be made of different materials (e.g. tungsten, metals, or other conductive materials) or nano-materials (nanowire, carbon nanotube). A gate layer 208 is formed on top of 206 dielectric pillars. The gate surrounds the tip and the dielectric forms a hollow chamber for the tip. The gate is also biased through the circuit layer 202. The structure 100 gets aligned to the microdevice and is brought close to the microdevice. The distance between microdevices is set so the spot size is not affecting adjacent devices or other components. The gate layer and the tips are biased and the microdevice contact 208 within the electron beam source structure is also biased to allow the electron to stream from the tip toward the microdevice. The current is controlled by the gate or the biasing of the tip or microdevices. Here, the substrate 200 can have tips only for fewer microdevices on the system substrate 108. As a result, only few microdevices turn on every time reducing the interference in measuring packed microdevices. In another case, there can be at least one tip associated with each microdevice on the substrate 108. In one case, the gate or tip or microdevice bias is controlled so that the spot size is small and only a few turns on at the time reducing the interference.

In another case, as demonstrated in FIG. 1D, there are more tips (electron sources) in the substrate 200 compared to the microdevices on the substrate 108. Therefore, the alignment accuracy requirement is less demanding. Here, the tips that are in the viewpoint or closer to the middle of the microdevice will provide electrons to the microdevice and activate the microdevice which means the tips and microdevices do not need to be aligned accurately. In addition, since each tip in a set of tips provides a smaller amount of current to the microdevice, there is less chance of damage to the microdevice. The smaller amount of current is less than a test current. For example if there are 10 tips per microdevice, the tip current is 1/10th of the test current. In case one tip is associated with the microdevice, it will provide a much larger current to a small area on the device contact 106 potentially causing damage. In addition, the lifetime of the tips will be higher with few smaller tips per microdevice due to lower current stress and redundancy effect. The number of tips is defined by the expected lifetime of test setup, what is the max current that a tip can operate under and meet the expected lifetime and the peak current of a microdevice. The microdevice peak current is divided by the tip pick current.

To protect the other surface and the microdevice from unwanted electron beams, FIG. 1E shows a protection electrode 104-3. Here the protection electrode 104-3 covers the critical area of the substrate 108. The critical part can be the transistors, capacitors, or other layers that can be damaged by the Ebeam. The electrode 104-3 is biased to collect the excess electron beams. Also, the electrode 104-2 that couples the circuitry 110 to the microdevice can be extended outside the microdevice to protect the important part of substrate 108 and circuitry 110. To protect the sidewall of the microdevice, an electrode 106-2 is formed to cover the sidewall and the top surface while it is coupled to the contact 106. The electrode 106-2 and contact 106 can be the same. A dielectric separates the sidewall of the microdevice from the electrode 106-2.

### Method Aspects

In one aspect of the invention, a method is disclosed to activate a microdevice with an electron beam, the method comprising, having the microdevice in a substrate, having an electron beam source, having at least one electrode of the microdevice biased by a second electrode or a probe, having the at least one electrode a part of biasing circuits in the substrate and activating the microdevice passing the electron beam through a pad to the microdevice to the at least one electrode. Here the biasing circuits can be simple electrode or pixel circuits with complex functions such as control of the duty cycle and signal strength. Also, a magnetic or an electric field is used to redirect the electron beam to different microdevices, wherein a distance of the electron beam source can be further away making a spot size of the electron beam larger.

The method can further comprise steps wherein the magnetic or the electric field can be used to direct the beam to a distance such that the current density stays within a threshold value followed by movement of the electron beam source to a new position. Also, a protective layer can cover surfaces on the substrate, part of the pads and microdevice surface. Here the protective layer can be a dielectric or a conductive layer redirecting the excess charge.

The method can further comprise the electron beam source having a structure with substrate with a circuit layer. Here the circuit layer may control a voltage or a current going through a tip. Here, the tip can be made of nano-materials including nanowire and carbon nanotube or other materials comprising tungsten, metal, or a conductive material. Also, a gate layer may surround the tip and a dielectric may form a hollow chamber for the tip where the gate layer is formed on top of dielectric pillars. Here the gate layer may be biased through a circuit layer in the electron beam source structure.

The method can further comprise wherein the electron beam source structure may be aligned to the microdevice and a distance between microdevices is set so that the spot size does not affect adjacent microdevices or other components. Here, the tip may be biased and microdevice contact within the electron beam source structure is also biased to allow the electron to stream from the tip towards the microdevice such that a current is controlled by the gate layer or the biasing of the tip or the microdevices. Here, the electron beam source substrate may have tips only for a lesser number of microdevices on the system substrate resulting in a lesser number of microdevices being on and reducing an interference. In addition, the electron beam source substrate may have more than one tip. Here, the tips that are in an alignment range of the microdevice may provide electrons to the microdevice and activate the microdevice and wherein each tip in a set of tips provides a smaller amount of current that is smaller than a test current to the microdevice. Further, a lifetime of the tips may be extended with few smaller tips per microdevice due to lower current stress and redundancy effect.

The method may further comprise, wherein a protection electrode may cover critical areas of the substrate and is biased to collect excess electron beams. In addition, an electrode coupling the biasing circuit to the microdevice may be extended outside the microdevice to protect a part of substrate and the circuitry.

The method may further comprise, wherein another electrode is formed to cover a sidewall and a top surface of the microdevice while it is coupled to the pad.

The method may further comprise, wherein the pad and the electrode covering the sidewall the same and a dielectric separates the sidewall from the electrode.

The method may further comprise, wherein there is at least one tip associated with each microdevice on the substrate.

The method may further comprise, wherein the gate or tip or microdevice bias is controlled so that the spot size is small and only a few microdevices turns on at the time, reducing the interference.

Further aspects of the method may include aspects of functionalities and related structure described in FIGURE descriptions.

While particular embodiments and applications of the present invention have been illustrated and described, it is to be understood that the invention is not limited to the precise construction and compositions disclosed herein and that various modifications, changes, and variations can be apparent from the foregoing descriptions without departing from the spirit and scope of the invention as defined in the appended claims. Further, a power of the electron beam can be modified to compensate a change in a current density.

1. A method to activate a microdevice with an electron beam, the method comprising:
having the microdevice in a substrate;
having an electron beam source;
having at least one electrode of the microdevice biased by a second electrode or a probe; having the at least one electrode a part of biasing circuits in the substrate; and activating the microdevice passing the electron beam through a pad to the microdevice to the at least one electrode.

2. The method of claim 1, wherein biasing circuits are a simple electrode or pixel circuits with complex functions representing control of the duty cycle and signal strength.

3. The method of claim 1, wherein a magnetic or an electric field is used to redirect the electron beam to different microdevices.

4. The method of claim 3, wherein a distance of the electron beam source is further away making a spot size of the electron beam larger.

5. The method of claim 4, wherein a power of the electron beam is modified to compensate a change in a current density.

6. The method of claim 1, wherein the magnetic or the electric field is used to direct the beam to a distance such that the current density stays within a threshold value followed by movement of the electron beam source to a new position.

7. The method of claim 1, wherein a protective layer covers surfaces on the substrate, part of the pads and microdevice surface.

8. The method of claim 7, wherein the protective layer is a dielectric or a conductive layer redirecting the excess charge.

9. The method of claim 1, wherein the electron beam source has a structure with substrate with a circuit layer, which controls a voltage or a current going through a tip.

10. (canceled)

11. (canceled)

12. The method of claim 9, wherein a gate layer surrounds the tip, which is made of tip is made of nano-materials including nanowire and carbon nanotube or other materials comprising tungsten, metal or a conductive material, and a dielectric forms a hollow chamber for the tip where the gate layer is formed on top of dielectric pillars.

13. The method of claim 12, wherein the gate layer is biased through a circuit layer in the electron beam source structure.

14. The method of claim 9, wherein the electron beam source structure is aligned to the microdevice and a distance between microdevices is set so that the spot size does not affect adjacent microdevices or other components.

15. The method of claim 13, wherein the tip is biased and microdevice contact within the electron beam source structure is also biased to allow the electron to stream from the tip towards the microdevice such that a current is controlled by the gate layer or the biasing of the tip or the microdevices.

16. The method of claim 15, wherein the electron beam source substrate has tips only for a lesser number of microdevices on the system substrate resulting in a lesser number of microdevices being on and reducing an interference.

17. The method of claim 9, wherein the electron beam source substrate has more than one tip.

18. The method of claim 17, wherein the tips that are in an alignment range of the microdevice will provide electrons to the microdevice and activate the microdevice.

19. The method of claim 18, wherein each tip in a set of tips provides a smaller amount of current that is smaller than a test current to the microdevice.

20. The method of claim 19, wherein a lifetime of the tips is extended with few smaller tips per microdevice due to lower current stress and redundancy effect.

21. The method of claim 1, wherein a protection electrode covers critical areas of the substrate and is biased to collect excess electron beams.

22. The method of claim 1, wherein an electrode coupling the biasing circuit to the microdevice is extended outside the microdevice to protect a part of substrate and the circuitry.

23. The method of claim 1, wherein another electrode is formed to cover a sidewall and a top surface of the microdevice while it is coupled to the pad.

24. The method of claim 1, wherein the pad and the electrode covering the sidewall are the same and a dielectric separates the sidewall from the electrode.

25. The method of claim 13, wherein there is at least one tip associated with each microdevice on the substrate.

26. The method of claim 25, wherein the gate or tip or microdevice bias is controlled so that the spot size is small and only a few microdevices turns on at the time, reducing the interference.
